(19) United States
(12) Patent Application Publication
(10) Pub. No.: US 2024/0281051 A1
(43) Pub. Date: Aug. 22, 2024

(54) INFORMATION OUTPUT DEVICE

(71) Applicant: DOT INCORPORATION, Seoul (KR)

(72) Inventors: Ju Yoon KIM, Gimpo-si (KR); Ji Ho KIM, Gimpo-si (KR); Hyeon Cheol PARK, Gwangmyeong-si (KR)

(21) Appl. No.: 18/651,287

(22) Filed: Apr. 30, 2024

Related U.S. Application Data
(63) Continuation-in-part of application No. 18/192,140, filed on Mar. 29, 2023, now Pat. No. 12,001,598.
(63) Continuation-in-part of application No. 18/086,166, filed on Dec. 21, 2022.
Application No. 18/192,140 is a continuation of application No. 17/099,174, filed on Nov. 16, 2020, now Pat. No. 11,635,801.
Application No. 18/086,166 is a continuation-in-part of application No. 17/099,174, filed on Nov. 16, 2020, now Pat. No. 11,635,801.
Application No. 17/099,174 is a continuation of application No. PCT/KR2019/005863, filed on May 16, 2019.

(30) Foreign Application Priority Data
May 16, 2018 (KR) 10-2018-0056173
Dec. 21, 2021 (KR) 10-2021-0184244

(51) Int. Cl. G06F 3/01; G08B 6/00; H05K 5/06

(52) U.S. Cl. CPC G06F 3/01; G08B 6/00; H05K 5/06

(57) ABSTRACT

An information output apparatus is proposed. The apparatus may include a casing comprising an expression surface and expression holes provided in the expression surface, protrusions configured to reciprocate so that at least a portion of each of the protrusions protrudes from a corresponding expression hole of the expression holes to display information on the expression surface. The apparatus may also include a driving module located inside the casing, connected to the protrusions, and configured to move the protrusions. The apparatus may further include a skin module comprising a film located opposite the expression surface, and a cover plate disposed along a circumference of the skin module to cover at least a portion of the circumference of the skin module.

### CROSS-REFERENCE TO RELATED APPLICATION

This application is a continuation-in-part of U.S. patent application Ser. No. 18/192,140 filed Mar. 29, 2023 and U.S. patent application Ser. No. 18/086,166 filed Dec. 21, 2022, respectively, a continuation and a continuation-in-part of U.S. patent application Ser. No. 17/099,174, filed Nov. 16, 2020, now U.S. Pat. No. 11,635,801 issued Apr. 25, 2023, which is a continuation of International Patent Application No. PCT/KR2019/005863, filed on May 16, 2019, which claims priority to Korean patent application No. 10-2018-0056173 filed on May 16, 2018. U.S. patent application Ser. No. 18/086,166 also claims priority to Korean patent application No. 10-2021-0184244 filed on Dec. 21, 2021. The contents of each of the above applications are incorporated herein by reference in their entireties.

### BACKGROUND

### Technical Field

One or more embodiments of the disclosure relate to an information output apparatus.

### Description of Related Technology

Users may recognize information in various ways. To this end, various types of information output apparatuses are being used.

For example, a visual information output apparatus using a printed material, an audio information output apparatus via sound, etc. are used.

In particular, according to an increase in an amount of information and development of technology, information output apparatuses using electronic technologies are widely used nowadays, and a display apparatus having a plurality of pixels is frequently used as a visual information output apparatus.

### SUMMARY

One or more embodiments of the disclosure provide an information output apparatus having an improved durability and being capable of improving user's convenience and providing waterproof and/or dampproof function.

One or more embodiments of the disclosure provide an information output apparatus capable of preventing deformation of a skin module that provides a waterproof and/or dampproof function during an assembly process or during in use, and securing durability.

An information output apparatus according to embodiment of the present disclosure may include: a casing comprising an expression surface and expression holes provided in the expression surface; protrusions configured to reciprocate so that at least a portion of each of the protrusions protrudes from a corresponding expression hole of the expression holes to display information on the expression surface; a driving module located inside the casing, connected to the protrusions, and configured to move the protrusions; a skin module comprising a film located opposite the expression surface; and a cover plate disposed along a circumference of the skin module to cover at least a portion of the circumference of the skin module.

Further, the information output apparatus may further include an active region in which the expression holes are located and a non-active region located at an edge of the active region, wherein the skin module comprises a rigidity module located to correspond to the non-active region.

Further, the cover plate may be disposed such that at least a portion thereof overlaps the skin module.

Further, the cover plate may include at least one recess.

In addition, the cover plate may include an inclined portion inclined in a direction to the expression surface.

Other aspects, features and advantages of the disclosure will become better understood through the accompanying drawings, the claims and the detailed description.

An information output apparatus according to one or more embodiments of the disclosure includes a skin module for protecting an expression surface, periphery of an expression hole, and/or a driving module against external moisture, damp, and/or contaminants, and accordingly, a durability of the information output apparatus may be improved.

Moreover, a waterproof function required for daily life and an underwater waterproof function are provided, and thus the information output apparatus may be used as a wearable device or may be used underwater.

One or more embodiments of the disclosure provide an information output apparatus capable of preventing deformation of a skin module that provides a waterproof and/or dampproof function during an assembly process or during in use, and securing durability.

### BRIEF DESCRIPTION OF THE DRAWINGS

FIG. 1 is a plan view of an information output apparatus according to an embodiment.

FIG. 2 is a cross-sectional view taken along line II-II of FIG. 1.

FIG. 3 is a cross-sectional view taken along line III-III of FIG. 1.

FIG. 4 is a cross-sectional view showing another example taken along line III-III of FIG. 1.

FIG. 5 is a cross-sectional view showing another example taken along line III-III of FIG. 1.

FIG. 6 is a partially cross-sectional view showing a portion of an information output apparatus according to another embodiment.

FIG. 7 is a partially cross-sectional view showing a portion of an information output apparatus according to another embodiment.

FIG. 8 is a cross-sectional view of an information output apparatus according to another embodiment.

FIG. 9 is a plan view of an information output apparatus according to an embodiment.

FIG. 10 is a cross-sectional view of an example of an active region of FIG. 9.

FIG. 11 is an exploded perspective view schematically showing a structure of an information output apparatus according to an embodiment of FIG. 9.

FIG. 12 is a diagram showing another example of a cross-sectional structure according to an embodiment.

FIG. 13 is a partially cross-sectional view showing a portion of an information output apparatus according to another embodiment.

FIG. 14 is a partially cross-sectional view showing a portion of an information output apparatus according to another embodiment.

FIG. 15 is a partially cross-sectional view showing a portion of an information output apparatus according to another embodiment.

FIG. 16 is a plan view of an information output apparatus according to another embodiment.

FIG. 17 is an exploded perspective view schematically showing the configuration of the information output apparatus shown in FIG. 16.

FIG. 18 is an enlarged view of part X of FIG. 16.

FIGS. 19 and 20 are partially cross-sectional views showing a portion of an information output apparatus according to an embodiment of FIG. 16.

FIG. 21 is a plan view schematically illustrating a modified example of an information output apparatus.

### DETAILED DESCRIPTION

Various forms of information output rather than the visual information output are required due to the development of technology, diversification of lifestyle, etc. This is because there is a limitation for a user in recognizing the visual information output.

For example, various information output apparatuses may be required according to a situation of each user, and in particular, when a user has a certain weakened sense, for example, when the user is visually impaired, it is necessary to output information through tactile sense.

Also, the information output apparatus through the tactile sense necessarily requires protruding movement of protrusions for implementing the tactile sense, and thus, there is a limitation in realizing a waterproof function and a durability of the information output apparatus degrades because the information output apparatus is vulnerable to contamination.

As the present disclosure allows for various changes and numerous embodiments, particular embodiments will be illustrated in the drawings and described in detail in the written description. The advantages and features of the embodiments and methods of achieving them will be apparent from the following embodiments that will be described in more detail with reference to the accompanying drawings. However, the embodiments may have different forms and should not be construed as being limited to the descriptions set forth herein.

The embodiments will be described below in more detail with reference to the accompanying drawings. Those components that are the same or are in correspondence are rendered the same reference numeral regardless of the figure number, and redundant explanations are omitted.

While such terms as “first,” “second,” etc., may be used to describe various components, such components must not be limited to the above terms. The above terms are used only to distinguish one component from another.

In all embodiments of the specification herein, a unit may denote a single component that executes a certain program, but is not limited thereto, and may be a partitioned area of at least one storage medium storing the program.

An expression used in the singular encompasses the expression of the plural, unless it has a clearly different meaning in the context.

In the present specification, it is to be understood that the terms such as “including,” “having,” and “comprising” are intended to indicate the existence of the features or components disclosed in the specification, and are not intended to preclude the possibility that one or more other features or components may exist or may be added.

Sizes of components in the drawings may be exaggerated for convenience of explanation. In other words, since sizes and thicknesses of components in the drawings are arbitrarily illustrated for convenience of explanation, the following embodiments are not limited thereto.

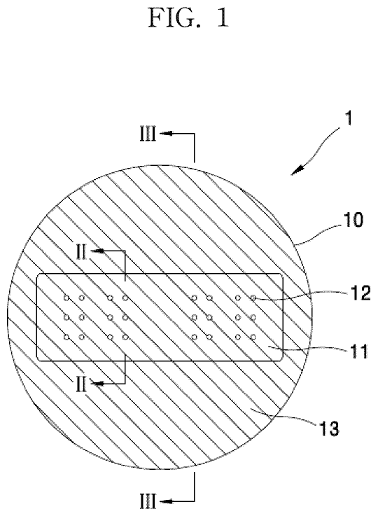

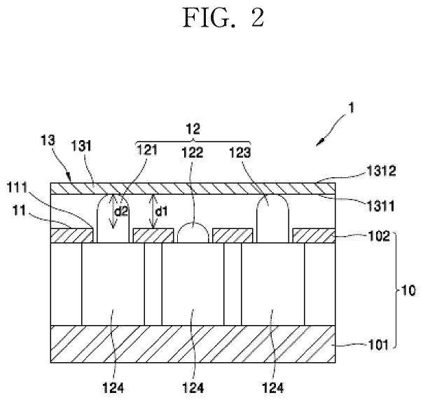

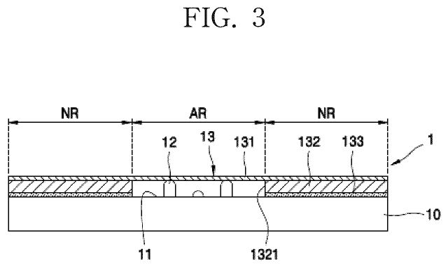

FIG. 1 is a plan view of an information output apparatus 1 according to an embodiment, and FIG. 2 is a cross-sectional view taken along line II-II of FIG. 1. FIG. 3 is a cross-sectional view taken along line III-III of FIG. 1.

The information output apparatus 1 according to the embodiment is provided to be portable, for example, may be provided in the form of a wrist watch worn on the wrist of a user or in the form of a portable terminal carried by the user. In addition, the information output apparatus 1 may be provided in the form of a wearable terminal that is in contact with a part of a user's body such that the user may feel through tactile sense. However, one or more embodiments are not limited thereto, and the information output apparatus may be an element attached to a building, equipment, and/or an apparatus.

Although not shown in the drawings, the information output apparatus 1 may communicate with a nearby computing device. The computing device may include a smart phone and/or a portable computer such as a tablet PC. The information output apparatus 1 may wirelessly communicate with the computing device via a near field and/or direct communication unit such as WiFi, Bluetooth, and/or NFC, but is not limited thereto, that is, the information output apparatus 1 may communicate with the computing device via wires.

The information output apparatus 1 may be provided to communicate with a server computer of various companies and/or institutions such as telecommunication companies, broadcasting companies, government agencies, etc., and these companies and/or institutions may receive information of various types through a wireless network, a wired network, and other various communication networks.

Referring to FIG. 1 and FIG. 2, the information output apparatus 1 may include a casing 10, protrusions 12, driving modules 124, and a skin module 13.

The casing 10 has a sealed internal space, in which the driving modules 124 may be accommodated.

The internal space of the casing 10 may be defined by a first casing 101 and a second casing 102 coupled to each other so as to face each other.

In FIG. 2, the driving module 124 is arranged to be in contact with an upper surface of the first casing 101 for convenience of description, but one or more embodiments of the disclosure are not limited thereto, that is, various elements such as a circuit board, a battery, and/or a controller for operating the driving module 124 may be further located between the driving module 124 and the first casing 101. Also, the first casing 101 may have a receptor structure for accommodating the elements.

In addition, the second casing is located facing the first casing 101, and the second casing 102 may include an expression surface 11 on at least a region of at least one outer surface thereof. The expression surface 11 may be a flat surface as shown in FIG. 2, but is not limited thereto, that is, the expression surface 11 may have various shapes, e.g., a curved surface, and/or a bent surface.

The second casing 102 may include expression holes 111 formed in the region that becomes the expression surface 11. Each of the expression holes 111 is provided such that the protrusion 12 may protrude from and may be pulled in the internal space of the casing 10, and at least a partial internal space of the casing 10 and the outside of the casing 10 may communicate with each other via the expression hole 111. The number of the expression holes 111 may correspond to the number of the protrusions 12.

There may be a plurality of driving modules 124, the number of which may correspond to the number of protrusions 12. The protrusions 12 and the driving modules 124 are coupled to each other in one-to-one correspondence, and each of the driving modules 124 may be electrically connected to a controller to be selectively driven. The driving module 124 may include an actuator that may be electrically driven.

The protrusions 12 may be located between the driving modules 124 and the second casing 102. The protrusions 12 are connected to the driving modules 124, and are operated according to the driving modules 124. The driving modules 124 and the protrusions 12 may be coupled to each other, but are not limited thereto, that is, the driving modules 124 and the protrusions 12 may be separated from each other and the protrusions 12 may be moved by receiving a driving force from the driving modules 124.

Each of the protrusions 12 may be located at a location corresponding to the expression hole 111, and at least a part of the protrusion 12 protrudes out of the expression hole 111 to provide a tactile expression to the user. The protrusion 12 may reciprocate to move in and move out of the expression hole 111, and although not shown in the drawings, a guide may be located adjacent to the expression hole 111 to guide the movement of the protrusion 12.

According to an embodiment, a plurality of protrusions 12 may be provided to represent special characters such as braille and to display a three-dimensional picture. The protrusion 12 may represent information by adjusting a protruding height out of the expression surface 11. For example, as shown in FIG. 2, a first protrusion 121, a second protrusion 122, and a third protrusion 123 adjacent to one another are provided. When the first protrusion 121 and the third protrusion 123 protrude to a maximum height and the second protrusion 122 protrude to a minimum height, the user may recognize that the first protrusion 121 and the third protrusion 123 protrude and may accordingly receive information.

The skin module 13 is located on an outer side of the casing 10, and as shown in FIG. 1, the skin module 13 may have an area that may at least cover the expression surface 11. Therefore, when the user may sense the skin module 13 first when sensing the expression surface 11 through the tactile sense, and may sense the movement of the protrusions 12, which is transferred through the tactile sense.

The skin module 13 may include a film 131.

The film 131 may be located facing at least the expression surface 11, and may extend along the expression surface 11.

The film 131 may include a first surface 1311 and a second surface 1312 facing each other, and the first surface 1311 may be arranged facing the expression surface 11. Therefore, the user may sense the second surface 1312 of the film 131 via the tactile sense.

The film 131 may include a material having flexibility and/or elasticity, and some degree of dampproof property, that is, the film 131 may include a polymer material, for example, polyurethane. Therefore, infiltration of moisture into the expression surface 11 via the film 131 may be prevented.

In addition, the film 131 may be formed not to have a large thickness, and the thickness of the film 131 may allow the user to feel the protruding state of the protrusion 12 under the film 131 when the user touches the second surface 1312 of the film 131.

The film 131 may be separated from the expression surface 11, and according to an embodiment, the film 131 may always maintain a separated state from the expression surface 11.

According to an embodiment, a separation distance d1 between the film 131 and the expression surface 11 may be equal to or greater than a maximum protruding height d2 of the protrusion 12 from the expression surface 11.

When the separation distance d1 between the film 131 and the expression surface 11 is less than the maximum protruding height d2 of the protrusion 12 from the expression surface 11, the first surface 1311 of the film 131 may be continuously hit due to the maximum protrusion of the protrusion 12, and thus, the film 131 may be damaged, and the protruding of the protrusion 12 may be interrupted and an overload may be applied to the driving module.

The separation distance d1 between the film 131 and the expression surface 11 may not be much greater than the maximum protrusion height d2 of the protrusion 12 from the expression surface 11, that is, a distance from the first surface 1311 of the film 131 to the end of the protrusion 12 in the maximum protruding state may correspond to a distance that the film 131 is pushed by the user touching the second surface 1312 such that the first surface 1311 may reach the protrusion 12. Accordingly, even when the first surface 1311 of the film 131 is separated from the end of the protrusion 12 that is in the maximum protruding state, the user may receive the information represented by the protrusion 12 via the second surface 1312.

The film 131 may include a material transmitting light, and accordingly, the user may observe information realized on the expression surface 11 from the outside of the film 131.

Referring to FIG. 3, according to the embodiment, the casing 10 may include an active region AR where the expression hole is located and a non-active region NR at an edge of the active region AR. The active region AR corresponds to a region in which the protruding of the protrusions 12 are activated and the expression is activated. In the embodiment or another embodiment, the active region AR may be a region in the expression surface 11, and the active region AR and the non-active region NR are partitioned in the expression surface 11.

The skin module 13 may further include a spacer 132 between the film 131 and the expression surface 11.

The spacer 132 may include an opening 1321 corresponding to the active region AR. Therefore, the protrusions 12 protrude from inside the opening 1321.

The spacer 132 may be bonded to the first surface 1311 of the film 131, and the separation of the film 131 from the expression surface 11 may be maintained by the spacer 132.

The spacer 132 may include a material that is harder than that of the film 131, but is not limited thereto, that is, may include a same kind of material.

An adhesive film 133 may be further provided between the spacer 132 and the casing 10. The spacer 132 may be fixedly attached to an outer surface of the casing 10 due to the adhesive film 133, and may form the internal region of the opening 1321, that is, the active region AR, as a sealed region that is shielded against the outside.

According to an embodiment, a sum of the thickness of the spacer 132 and the adhesive film 133 may be equal to the separation distance d1 between the film 131 and the expression surface 11 described above.

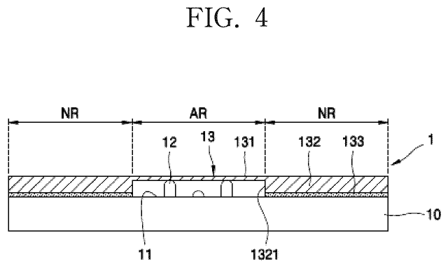

FIG. 4 is a cross-sectional view showing another example of the information output apparatus taken along line III-III of FIG. 1.

According to the embodiment illustrated with reference to FIG. 4, the spacer 132 and the film 131 may be integrally formed. That is, in a film including a single material, a thin groove is processed in a region corresponding to the active region AR, and then, the groove region becomes the film 131 and unprocessed region may maintain the thickness.

A film assembly in which the spacer 132 and the film 131 are integrally provided may be bonded to the casing 10 via the adhesive film 133.

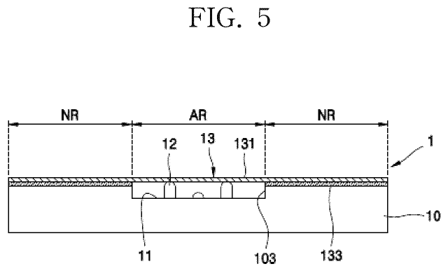

FIG. 5 is a cross-sectional view showing another example of the information output apparatus taken along line III-III of FIG. 1.

According to the embodiment illustrated with reference to FIG. 5, the casing 10 may include a groove 103 corresponding to the active region AR. Here, the expression surface 11 may be located inside the groove 103.

In this embodiment, the skin module 13 may only include the film 131 except for the spacer, and the film 131 may be attached to a surface of the casing 10 outside the groove 103 via the adhesive film 133.

According to an embodiment, a sum of a depth of the groove 103 and the thickness of the adhesive film 133 may be equal to the separation distance d1 between the film 131 and the expression surface 11 described above.

Although not shown in the drawings, the embodiments illustrated with reference to FIG. 3 to FIG. 5 may be combined to generate a new embodiment. For example, the skin module 13 including the spacer 132 shown in FIG. 2 and/or FIG. 3 may be coupled to the casing 10 having the groove 103 as in the embodiment of FIG. 5.

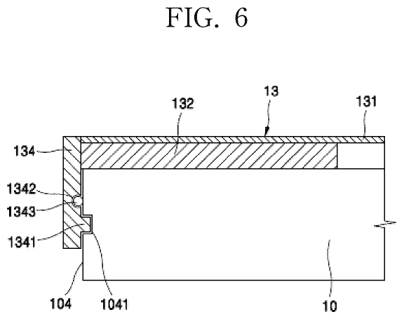

FIG. 6 is a cross-sectional view partially showing an information output apparatus according to another embodiment.

Referring to FIG. 6, the information output apparatus according to another embodiment of the disclosure may include a first coupling unit 1041 located in at least a part of the casing 10 and a second coupling unit 1341 located on the skin module 13.

The skin module 13 may include further include a support unit 134 coupled to at least an edge of the film 131. According to an embodiment, the support unit 134 may be fixedly coupled to the edges of the film 13 and the spacer 132. In an embodiment in which a spacer is not necessary, the support unit 134 would be fixedly coupled to the edge of the film 131.

The support unit 134 may extend from the edge of the film 13 towards a side surface 104 of the casing 10, and may be located facing the side surface 104.

The support unit 134 may include plastic and/or metal, and may have a certain degree of elasticity in a direction perpendicular to a lengthwise direction thereof.

The second coupling unit 1341 may be located on the support unit 134, and according to an embodiment, the second coupling unit 1341 may be on a surface of the support unit 134, the surface facing the side surface 104.

The second coupling unit 1341 is provided to be coupled to the first coupling unit 1041 formed in the side surface 104. Therefore, when the first coupling unit 1041 is formed as a groove as shown in FIG. 6, the second coupling unit 1341 may be formed as a protrusion that may be inserted into the groove. The groove and the protrusion are not limited to rectangular shapes as shown in the drawings, but may have various shapes such as a semicircular shape, a semi-elliptical shape, a fan shape, a triangular shape, a pentagonal shape, etc. Also, the first coupling unit 1041 may be formed as a protrusion and the second coupling unit 1341 may be formed as a groove.

According to the above structure, the skin module 13 may be detachably coupled to the casing 10 without using a separate adhesive film, and thus, the user may easily replace the skin module 13. Therefore, when the film 131 is worn, the skin module 13 may be replaced to maintain the sealing property of the active region AR. Moreover, the skin module 13 may be provided to have the film 131 of various colors, and thus, the user may selectively attach the skin module 13 having the film 131 of a desired color to the casing 10.

According to another embodiment, the information output apparatus may further include a first sealing unit 1343 between the support unit 134 and the side surface 104 of the casing 10 as shown in FIG. 6. For mounting the first sealing unit 1343, the support unit 134 may include a first mounting recess 1342 on a region facing the side surface 104, and when the first sealing unit 1343 is mounted in the first mounting recess 1342, the first sealing unit 1343 may be fixedly located between the casing 10 and the support unit 134.

A location where the first sealing unit 1343 is mounted may be closer to the film 131 than the first coupling unit 1041 and the second coupling unit 1341 described above.

Infiltration of the moisture and damp into the active region AR from the outside may be blocked by the first sealing unit 1343, and moreover, introduction of other contaminants such as dust into the active region AR may be prevented.

The first sealing unit 1343 may include a material that may be elastically compressible, and as shown in FIG. 6, the first sealing unit 1343 may be partially and forcibly fitted into the first mounting recess 1342 of the support unit 134. However, one or more embodiments are not limited thereto, that is, the first sealing unit 1343 may be bonded to the first mounting recess 1342. Selectively, the first sealing unit 1343 may be bonded to the surface of the support unit 134, the surface facing the casing 10, without using the first mounting recess 1342.

The first sealing unit 1343 may be formed to form a closed loop, for example, a closed loop surrounding at least the expression surface. Accordingly, at least the expression surface may be encapsulated against the external moisture, damp, and/or contaminants.

In the embodiment illustrated with reference to FIG. 6, the skin module 13 includes the film 131 and the spacer 132, but one or more embodiments are not limited thereto, that is, the disclosure may be also applied to an embodiment in which the spacer 132 is integrally provided with the film 131 and an embodiment in which the skin module 13 includes the groove 103 formed in the casing 10 and the film 131.

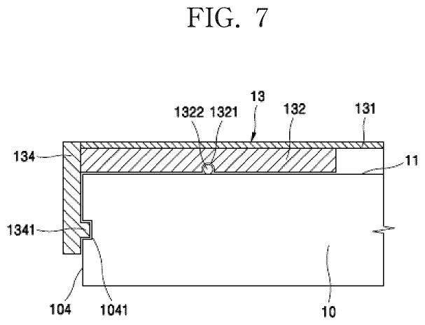

FIG. 7 is a partially cross-sectional view showing a portion of an information output apparatus according to another embodiment.

According to the embodiment illustrated with reference to FIG. 7, a second sealing unit 1322 may be located between the film 131 and the casing 10, not on the support unit 134.

According to an embodiment, the second sealing unit 1322 may be between the spacer 132 and the expression surface 11 of the casing 10. For mounting the second sealing unit 1322, the spacer 132 may include a second mounting recess 1321 in a region facing the expression surface 11, and when the second sealing unit 1322 is mounted in the second mounting recess 1321, the second sealing unit 1322 may be fixedly located between the casing 10 and the spacer 132.

Infiltration of the moisture and damp into the active region AR from the outside may be blocked by the second sealing unit 1322, and moreover, introduction of other contaminants such as dust into the active region AR may be prevented.

The second sealing unit 1322 may include a material that may be elastically compressible, and as shown in FIG. 7, the second sealing unit 1322 may be partially and forcibly fitted into the second mounting recess 1321 of the spacer 132. However, one or more embodiments are not limited thereto, that is, the second sealing unit 1322 may be bonded to the second mounting recess 1321. Selectively, the second sealing unit 1322 may be bonded to the surface of the spacer 132, the surface facing the casing 10, without using the second mounting recess 1321.

The second sealing unit 1322 may be formed to form a closed loop, for example, a closed loop surrounding at least the expression surface. Accordingly, at least the expression surface may be encapsulated against the external moisture, damp, and/or contaminants.

In the embodiment illustrated with reference to FIG. 7, the skin module 13 includes the film 131 and the spacer 132, but one or more embodiments are not limited thereto, that is, the disclosure may be also applied to an embodiment in which the spacer 132 is integrally provided with the film 131 and an embodiment in which the skin module 13 includes the groove 103 formed in the casing 10 and the film 131.

Although not shown in the drawings, the information output apparatus according to another embodiment may include both the first sealing unit 1343 of FIG. 6 and the second sealing unit 1322 of FIG. 7. Accordingly, the sealing property with respect to at least the expression surface may be further improved, and the waterproof characteristic of the information output apparatus may be implemented.

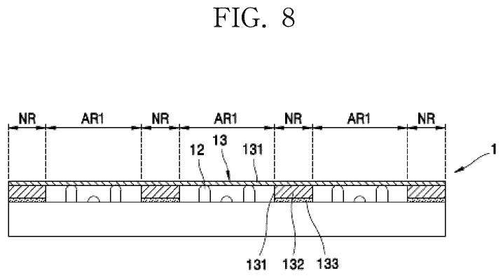

FIG. 1 and FIG. 3 show one active region AR and one non-active region NR surrounding the active region AR, but one or more embodiments are not limited thereto, that is, a plurality of active regions AR and a plurality of non-active regions NR may be formed as shown in FIG. 8.

The embodiment illustrated with reference to FIG. 8 may be combined with all the embodiments described above.

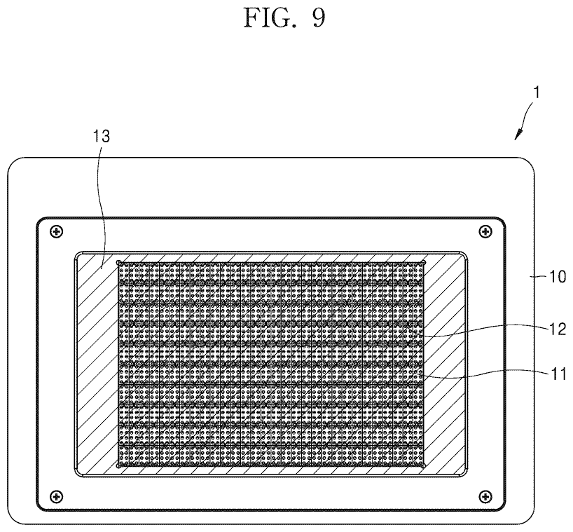

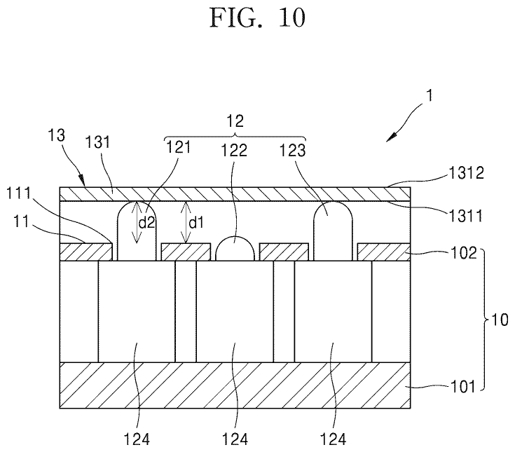

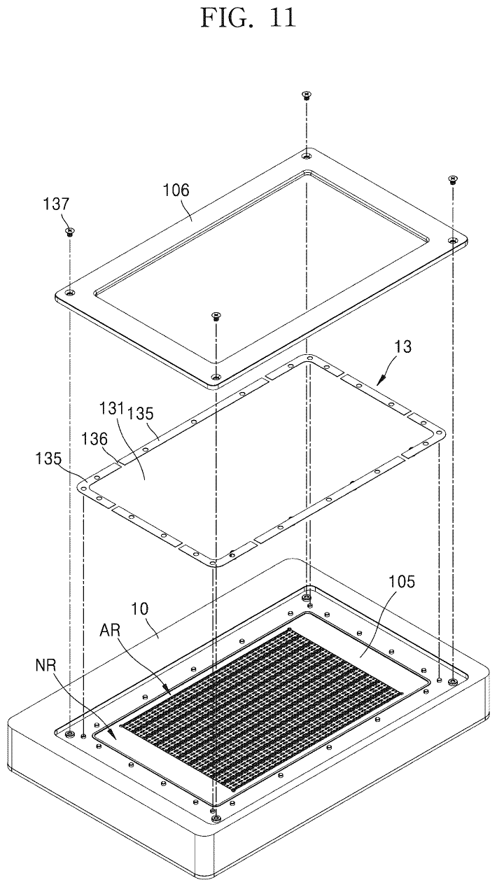

FIG. 9 is a plan view of an information output apparatus 1 according to an embodiment, FIG. 10 is a diagram showing an example of a cross-sectional structure of an active region of FIG. 9, and FIG. 11 is an exploded perspective view schematically showing an information output apparatus according to an embodiment of FIG. 9. Hereinafter, like reference numerals denote like elements, and descriptions about the elements described above will be omitted.

Referring to FIG. 11, according to the embodiment, the information output apparatus 1 may include an active region AR where the expression hole is located and a non-active region NR at an edge of the active region AR. The active region AR corresponds to a region in which the protruding of the protrusions 12 are activated and the expression is activated. In the embodiment or another embodiment, the active region AR may be a region in the expression surface 11, and the active region AR and the non-active region NR are partitioned in the expression surface 11.

As shown in FIG. 11, the skin module 13 may include a rigidity module 135 in at least a part thereof.

The rigidity module 135 may be implemented to have a greater rigidity than an average rigidity of a film 131 forming the skin module 13, for example, may have a structure in which a hard plastic material or metal material is bonded to the film 131.

The rigidity module 135 may be formed in a bar shape that is narrow and long, or a flat plate shape.

According to an embodiment, the rigidity module 135 may be bonded to the film 131 via an adhesive interposed therebetween, but is not limited thereto, that is, may be bonded to the film 131 in the manner of a thermocompression bonding method, an ultrasonic bonding method, etc.

The film 131 may be coupled to the rigidity module 135 while being uniformly tensioned throughout the planar direction of the corresponding film 131. Tensioning of the film 131 may be carried out in correspondence with a planar shape of the device to which the skin module 13 is coupled. In detail, when the device has a rectangular plane structure as shown in FIG. 9, the film 131 may be coupled to the rigidity module 135 while being tensioned in transverse and longitudinal directions. Although not shown in the drawings, when the device has a circular plane structure, the film may be coupled to the rigidity module 135 while being uniformly tensioned in a circumferential direction of the circle. As described above, because the film 131 is tensioned and coupled to the rigidity module 135 and then the skin module 13 is coupled to the device, sagging or stretching of the film 131 may be prevented during in use of the device, a waterproof property may be stably provided to the user, and at the same time, degradation in a touch sensitivity with respect to a tactile module may be prevented.

The rigidity module 135 may be arranged along edges of the film 131. An elasticity of the film 131 may be maintained for a certain period of time due to the rigidity module 135, and total durability may be improved.

Alternatively, the rigidity module 135 may be arranged to form a discontinuous loop along the edges of the film 131. Therefore, a plurality of rigidity modules 135 may be arranged to be adjacent to one another, and a gap 136 may be between the rigidity modules 135. A width of the gap 136 may be less than a length and/or a width of the rigidity module 135.

As described above, because the film 131 is coupled to the rigidity module 135 while being tensioned, the film 131 may be rather warped because of the rigidity module 135. When the rigidity modules 135 are formed in the discontinuous loop, the film 131 may not be deformed, e.g., may not be warped, throughout the entire area thereof due to the rigidity module 135. When the rigidity module 135 forms a continuous closed loop along the edges of the film 131, handling property may degrade due to the tensile force of the film 131 and a flatness may degrade, e.g., the film 131 may be warped. Therefore, when the rigidity modules 135 are formed in the form of the discontinuous loop, the skin module 13 may be easily assembled without warping the film 131, and the effect of maintaining the tension of the film 131 due to the rigidity module 135 may be continued.

The skin module 13 may be coupled to a support 105 on an outer side of the expression surface in the casing 10 while the rigidity module 135 is arranged corresponding to the non-active region NR.

A cover plate 106 may be further provided to cover the support 105 to which the skin module 13 is coupled. The cover plate 106 may be coupled to the support 105 so as to cover the rigidity module 135, and according to an embodiment, the cover plate 106 may be coupled to the support 105 to be attachable/detachable. Accordingly, the user may exchange the skin module 13 after uncovering the cover plate 106.

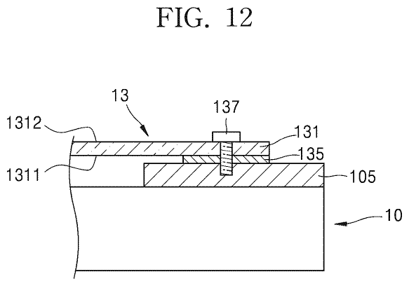

FIG. 12 is a partially cross-sectional view showing a portion of an information output apparatus according to an embodiment. The information output apparatus according to the embodiment may be arranged so that the rigidity module 135 comes into contact with the first surface 1311 of the film 131 as shown in FIG. 12.

That is, the rigidity module 135 may be interposed between the film 131 and the support 105. In addition, fixing bolts 137 may be fastened with the support 105 so as to pass through the edges of the film 131 and the rigidity module 135, and thus, the skin module 13 may be firmly fixed to the support 105.

The fixing bolts 137 may pass through the rigidity module 135 without being located in the gaps 136 as shown in FIG. 11. In this case, the rigidity module 135 may be implemented as a plate shape that is formed as thin as possible.

In the embodiment of FIG. 12, because the waterproof performance may degrade due to the gap 136 between the rigidity modules 135, the rigidity module 135 may be formed in a continuous closed loop shape.

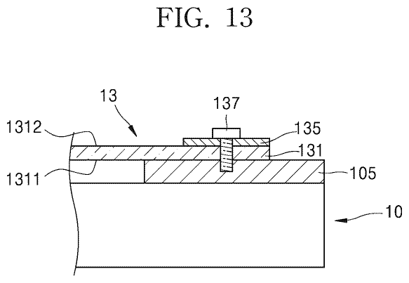

FIG. 13 is a partially cross-sectional view showing a portion of an information output apparatus according to another embodiment.

Unlike the embodiment shown in FIG. 12, the skin module 13 is bonded to the support 105 via an adhesive member 138 such as a dual-adhesive tape according to the embodiment of FIG. 13. The adhesive member 138 may not necessarily have a strong adhesive force, but may have an adhesive force to a degree that allows the user to detach by the force of him/herself so that the skin module 13 may be attached/detached by the user. When the skin module 13 is bonded via the adhesive member 138, the waterproof property may be further improved.

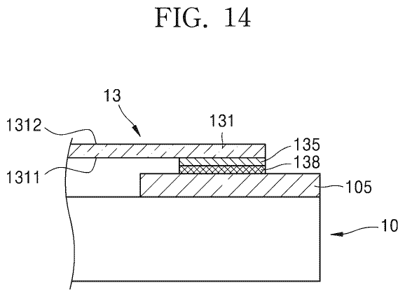

FIG. 14 is a partially cross-sectional view showing a portion of an information output apparatus according to another embodiment.

Unlike the embodiment of FIG. 12, the rigidity module 135 may be arranged to come into contact with the second surface 1312 of the film 131 according to the embodiment of FIG. 14. That is, the rigidity module 135 may be interposed between the film 131 and the cover plate 106 (see FIG. 11). In addition, the fixing bolts 137 are fastened with the support 105 so as to pass through the edges of the rigidity module 135 and the film 131, and thus, the skin module 13 may be firmly fixed to the support 105.

The fixing bolts 137 may pass through the rigidity module 135 without being located in the gaps 136 as shown in FIG. 11. In this case, a head portion of the fixing bolt 137 is fastened while coming into contact with the rigidity module 135, and thus, the fastening force of the fixing bolt 137 may be further improved.

In addition, even when the rigidity modules 135 are formed in the form of discontinuous loop, the waterproof property may be maintained.

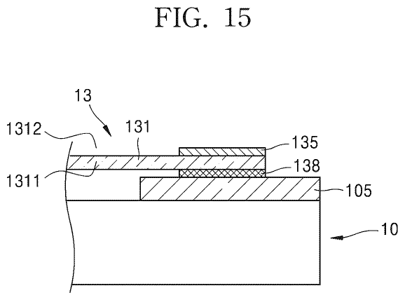

FIG. 15 is a partially cross-sectional view showing a portion of an information output apparatus according to another embodiment.

Unlike the embodiment shown in FIG. 14, the skin module 13 is bonded to the support 105 via an adhesive member 138 such as a dual-adhesive tape according to the embodiment of FIG. 15. The adhesive member 138 may not necessarily have a strong adhesive force, but may have an adhesive force to a degree that allows the user to detach by the force of him/herself so that the skin module 13 may be attached/detached by the user. When the skin module 13 is bonded via the adhesive member 138, the waterproof property may be further improved.

Hereinafter, an information output apparatus 1 according to another embodiment of the present disclosure will be described. The information output apparatus 1 according to the present embodiment differs in the configuration of a cover plate 14 compared to the information output apparatus 1 described with reference to FIGS. 9 to 11 and the like. Therefore, for ease of description, configurations that are identical to the foregoing embodiments or that may be easily changed by a person having ordinary knowledge in the technical field to which the present disclosure pertains will be omitted or abbreviated hereinafter.

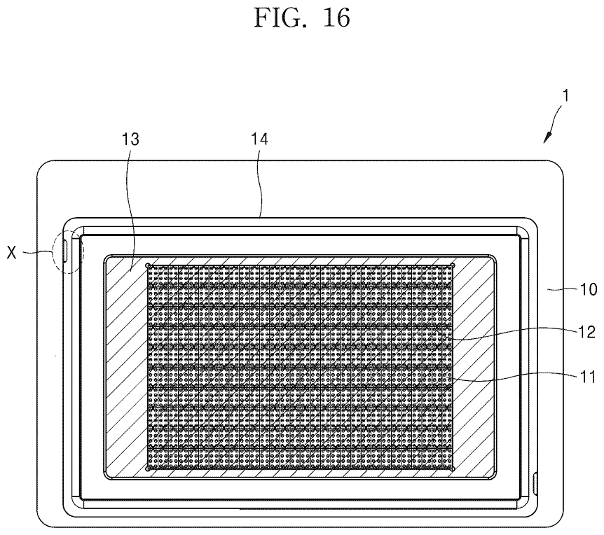

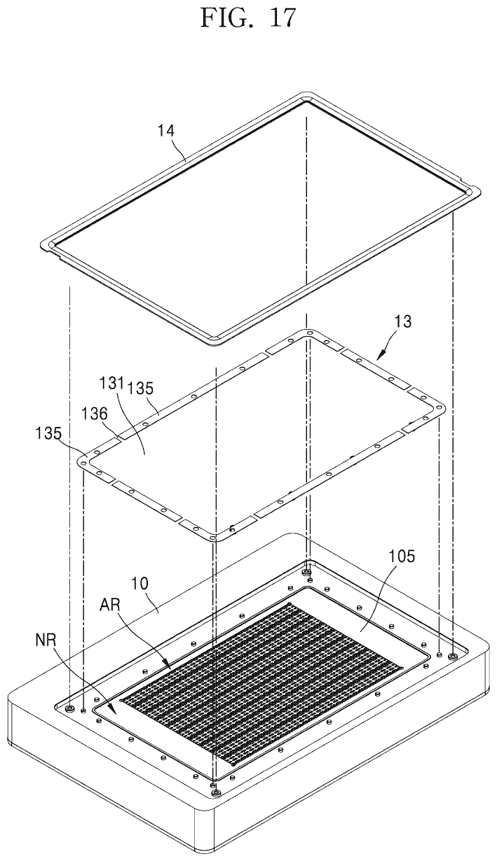

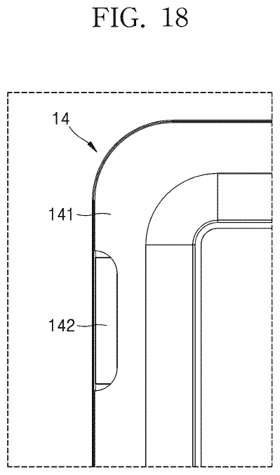

FIG. 16 is a plan view of an information output apparatus according to another embodiment. FIG. 17 is an exploded perspective view schematically showing the configuration of the information output apparatus shown in FIG. 16. FIG. 18 is an enlarged view of part X of FIG. 16.

Referring to FIGS. 16 to 18, the information output apparatus 1 according to the present embodiment may include the cover plate 14.

The cover plate 14 may be disposed around a skin module 13. For example, the cover plate 14 may be coupled to a support 105 to cover a rigidity module 135.

According to an embodiment, the cover plate 14 may be coupled to the support 105 to be attachable/detachable. Accordingly, the user may uncover the cover plate 14 and exchange the skin module 13.

After the skin module 13 is disposed in the casing 10, the cover plate 14 may be disposed around the skin module 13. In this case), as shown in FIG. 16, the cover plate 14 may be disposed in a non-active region NR.

The cover plate 14 may cover at least a portion of the circumference of the skin module 13. Covering at least a portion of the circumference of the skin module 13 with the cover plate 14 means that after the skin module 13 is disposed on an outer portion of the casing 10, the cover plate 14 is disposed above the skin module 13 to cover at least a portion of the circumference of the skin module 13.

The cover plate 14 may be formed substantially in the shape of a ring. For example, the cover plate 14 may be formed substantially in the shape of a schematic square having a hollow internal space. That is, the cover plate 14 may be a square ring having a hollow space therein.

However, the cover plate is not limited thereto, and may be formed in the shape of a continuous closed loop having circular, oval, or other polygonal shapes as desired.

Even in a case where the cover plate 14 is located to cover the skin module 13, at least a portion of a film 131 may be exposed to the outside through the space formed within the cover plate 14. Therefore, even in a case where the cover plate 14 is located around the skin module 13, the user may sense a second surface of the film 131 via the tactile sense.

Referring to FIGS. 16 and 18, the cover plate 14 may include a body 141 and a recess 142.

The body 141 may form the overall shape of the cover plate 14.

In addition, the cover plate 14 may be further provided with at least one recess 142. That is, the body 141 may be further provided with at least one recess 142.

The recess 142 is formed to allow the user to easily remove the cover plate 14 by inserting a finger or the like into the recess 142 when removing the cover plate 14 from the support 105.

In an embodiment, the recess 142 may be formed from the outer circumferential surface of the cover plate 14 to the inner circumferential surface. For example, the recess 142 may be formed in a shape recessed from the outer circumference of the cover plate 14 to an expression surface 11.

At least one recess 142 may be formed along the outer circumferential surface of the cover plate 14. For example, a single recess 142 may be formed on each of opposite sides of the cover plate 14, or two or more recesses 142 may be formed on each of the opposite sides of the cover plate 14. Alternatively, one or more recesses 142 may be formed on each of a plurality of sides of cover plate 14, but is not limited thereto. Here, because the waterproof function may degrade due to the recesses 142, the recesses 142 may be formed in a suitable number to facilitate removal of the cover plate 14.

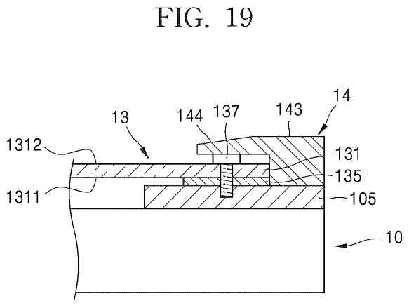

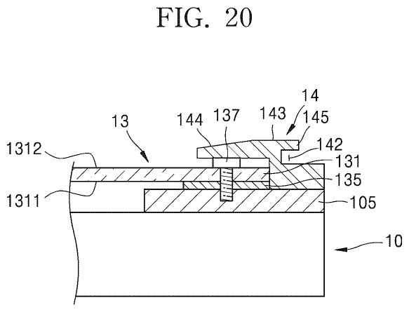

FIGS. 19 and 20 are partially cross-sectional views showing a portion of an information output apparatus according to an embodiment of FIG. 16.

Here, FIG. 19 is a view showing a portion of the cross-section not passing through the recess 142 in the information output apparatus 1 of FIG. 16, and FIG. 20 is a view showing a portion of the cross-section passing through the recess 142 in the information output apparatus 1 of FIG. 16.

Referring to FIG. 19, the cover plate 14 may be disposed to cover the support 105. When describing the cover plate 14 from an assembly perspective, the cover plate 14 may be described as being fitted into the space defined between the skin module 13 and the casing 10.

The cover plate 14 may be disposed to overlap at least a region of the skin module 13. In a specific embodiment, the cover plate 14 may be disposed to overlap at least a region of the film 131. In this case, the cover plate 14 may be formed such that at least a portion thereof extends in a direction from the outer circumference to the inside. That is, the cover plate 14 may cover at least a portion of the film 131.

In this context, the cover plate 14 overlapping at least a portion of the skin module 13 includes both a case where the cover plate 14 is in contact with the skin module 13 and a case where the cover plate 14 is spaced apart from the skin module 13. That is, the cover plate 14 may extend inward to contact a portion of an upper surface of the skin module 13 or may extend inward while being spaced apart from the skin module 13.

The cover plate 14 may include a planar portion 143 and an inclined portion 144.

The planar portion 143 may be a portion of the circumference of the cover plate 14 extending flatly inward from an outer portion of the cover plate 14. Here, the planar portion 143 does not necessarily mean a portion extending perfectly parallel to the casing 10, but may be defined as flat to the extent of being schematically parallel.

The inclined portion 144 is a portion inclined in a direction from the planar portion 143 to the expression surface 11. The inclined portion 144 may be formed inside the planar portion 143. In an example, the inclined portion 144 alone may form a single closed loop.

The space defined inside the cover plate 14 by the inclined portion 144 may be formed in the shape of a recess. That is, the space defined inside the cover plate 14 may be formed in a caved-in shape. Accordingly, when the cover plate 14 is mounted on the support 105, the film 131 may be located inside the cover plate 14. That is, the film 131 may be disposed at a lower position than a side formed by the planar portion 143.

Accordingly, the user may recognize via tactile sense which portion of the inclined portion 144 of the cover plate 14 is an area on which information is displayed by means of the protrusions 12. That is, the user may expect that the information will be displayed by means of the protrusions 12 on the inside of the area enclosed by the inclined portion 144.

Referring to FIG. 20, the recess 142 may be formed in a shape recessed from the outside to the inside of the cover plate 14.

Here, when a direction from the outer circumference to the inside of the cover plate 14 (i.e., a left-right direction in FIG. 20) is referred to as a width direction and a direction from the upper surface of the cover plate 14 to the support 105 (i.e., an up-down direction in FIG. 20) is referred to as a height direction, the recess 142 may be concave from the outside of the cover plate 14 in both the width direction and the height direction.

In an embodiment, the cover plate 14 may further include a protrusion 145 protruding outward from the planar portion 143. A space may be defined below the protrusion 145. Thus, the user may easily remove the cover plate 14 by inserting a finger into the recess 142, hooking the protrusion 145 with the finger, and then pulling the cover plate 14 outward. That is, because the space is formed below the protrusion 145 in both the height and width directions, the user's finger may rest in the recess 142. In another expression, the user may easily remove the cover plate 14 by hooking the finger on the protrusion 145.

In FIGS. 19 and 20, the cover plate 14 is shown as being mounted on the information output apparatus 1 described with reference to FIG. 4, but is not limited thereto, and it will be appreciated that the cover plate 14 may also be mounted on the information output apparatus 1 described with reference to FIGS. 5 to 7.

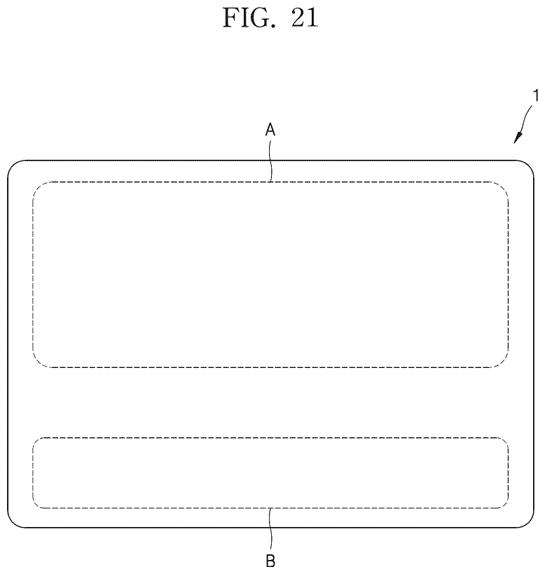

FIG. 21 is a plan view schematically illustrating a modified example of an information output apparatus 1.

Referring to FIG. 21, the information output apparatus 1 according to an embodiment may include a plurality of active regions AR and a corresponding plurality of non-active regions NR. In each of the active regions AR, protrusions 12, a driving module 124, and a skin module 13 may be disposed. That is, the information output apparatus 1 may have a plurality of expression surfaces 11 spaced apart from each other, and a plurality of expression holes 111 may be formed on each of the expression surfaces 11. In addition, each of the expression holes 111 may be provided with protrusions 12, and a driving module 124 may be provided to protrude and retract the protrusions 12.

When described from another perspective, the information output apparatus 1 according to the present embodiment may include a plurality of active regions AR as described in the foregoing embodiments.

In an alternative embodiment, the plurality of active regions AR may be formed to have different sizes. In this case, the number of expression holes 111, the protrusions 12, and the driving modules 124 disposed in each of the active regions AR may vary.

In an alternative embodiment, the plurality of active regions AR may provide different information. For example, a single active region AR may represent an image, and another active region AR may represent a letter or a number. However, the present disclosure is not limited thereto, and each of the active regions may provide different information such as images, characters, symbols, shapes, and numbers.

On the other hand, when a plurality of active regions AR are formed in the information output apparatus 1 as described above, the skin module 13 and the cover plate 14 may be disposed outside each of the active regions AR, for example, in each of the non-active regions NR.

The embodiments described above in the present specification may be applied in combination with each other.

In the information output apparatus according to the embodiments, the expression hole is formed in the expression surface, and the protrusion repeatedly protrudes through the expression hole, and thus, the protrusion and the expression hole may be separated a certain distance from each other. In addition, the driving module connected to the protrusion is located right inside the expression hole, and when moisture, damp, and/or contaminants are infiltrated into the information output apparatus through the expression hole or attached around the expression hole, a durability of the information output apparatus may degrade.

The information output apparatus according to the embodiments include the skin module so as to protect the expression surface against the external moisture, damp, and/or contaminants, and accordingly, the durability of the information output apparatus may be improved.

Moreover, a waterproof function required for daily life and an underwater waterproof function are provided, and thus the information output apparatus may be used as a wearable device or may be used underwater.

While the disclosure has been particularly shown and described with reference to exemplary embodiments thereof, it will be understood by those of ordinary skill in the art that various changes in form and details may be made therein without departing from the spirit and scope as defined by the following claims. Therefore, the scope sought to be protected of the disclosure shall be defined by the appended claims.

The particular implementations shown and described herein are illustrative examples of the embodiments and are not intended to otherwise limit the scope of the embodiments in any way. For the sake of brevity, electronics, control systems, software, and other functional aspects of the systems according to the related art may not be described in detail. Furthermore, the connecting lines or connectors shown in the drawings are intended to represent example functional relationships and/or physical or logical couplings between the various elements. It should be noted that many alternative or additional functional relationships, physical connections, or logical connections may be present in a practical device. Moreover, no item or component is essential to the practice of the disclosure unless the element is specifically described as “essential” or “critical”.

The singular forms “a,” “an” and “the” in the specification of the embodiments, in particular, claims, may be intended to include the plural forms as well. Unless otherwise defined, the ranges defined herein is intended to include values within the range as individually applied and may be considered to be the same as individual values constituting the range in the detailed description. Finally, operations constituting methods may be performed in appropriate order unless explicitly described in terms of order or described to the contrary. Exemplary embodiments are not necessarily limited to the order of operations given in the description. The examples or exemplary terms (for example, etc.) used herein are to merely describe exemplary embodiments in detail are not intended to limit the embodiments unless defined by the following claims. Also, those of ordinary skill in the art will readily appreciate that many alternations, combinations and modifications, may be made according to design conditions and factors within the scope of the appended claims and their equivalents.

What is claimed is:

1. An information output apparatus comprising:
a casing comprising an expression surface and expression holes provided in the expression surface;
protrusions configured to reciprocate so that at least a portion of each of the protrusions protrudes from a corresponding expression hole of the expression holes to display information on the expression surface;
a driving module located inside the casing, connected to the protrusions, and configured to move the protrusions;
a skin module comprising a film located opposite the expression surface; and
a cover plate disposed along a circumference of the skin module to cover at least a portion of the circumference of the skin module.

2. The information output apparatus of claim 1, further comprising an active region in which the expression holes are located and a non-active region located at an edge of the active region,
wherein the skin module comprises a rigidity module located to correspond to the non-active region.

3. The information output apparatus of claim 1, wherein the cover plate is disposed such that at least a portion thereof overlaps the skin module.

4. The information output apparatus of claim 1, wherein the cover plate comprises at least one recess.

5. The information output apparatus of claim 1, wherein the cover plate comprises an inclined portion inclined in a direction to the expression surface.
